(19) United States
(12) Patent Application Publication
(10) Pub. No.: US 2025/0344456 A1
(43) Pub. Date: Nov. 6, 2025

(54) INTERCONNECT STRUCTURE FOR SEMICONDUCTOR DEVICE

(71) Applicant: Taiwan Semiconductor Manufacturing Company, Ltd., Hsinchu (TW)

(72) Inventors: Kuo-Chiang TSAI, Hsinchu City (TW); Pei-Hsuan LIN, Hsinchu City (TW); Jeng-Ya YEH, New Taipei City (TW); Mu-Chi CHIANG, Hsinchu (TW)

(21) Appl. No.: 19/272,649

(22) Filed: Jul. 17, 2025

Related U.S. Application Data
(62) Division of application No. 17/812,991, filed on Jul. 15, 2022.
(60) Provisional application No. 63/362,469, filed on Apr. 5, 2022.

(51) Int. Cl. H10D 30/67; H01L 21/768; H10D 62/10; H10D 64/01; H10D 64/23; H10D 84/01; H10D 84/03

(52) U.S. Cl. CPC H10D 30/6757; H01L 21/76897; H10D 30/6735; H10D 62/119; H10D 64/017; H10D 64/254; H10D 84/0149; H10D 84/038

(57) ABSTRACT

A method and device according to the present disclosure includes a substrate that has a first transistor terminal such as a source feature and a second transistor terminal such as another source feature. Contact structures are formed on each source/drain feature. After forming the contact structures, a via opening is formed in dielectric materials above the contact structures, which is filled to form a non-linear via that extends from the contact on the first source feature to the contact on the second source feature. The non-linear via may include an outline in a top view of an undulating-shape having convex and/or concave portions.

### PRIORITY DATA

The present application is a divisional application of U.S. patent application Ser. No. 17/812,991, filed Jul. 15, 2022, which claims the benefit of U.S. Provisional Patent Application No. 63/362,469, filed Apr. 5, 2022, entitled “VIA STRUCTURE FOR SEMICONDUCTOR DEVICES AND METHODS OF FABRICATING THEREOF,” herein incorporated by reference in their entireties.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). The three-dimensional structure of the multi-gate devices, allows them to be aggressively scaled while maintaining gate control and mitigating SCEs. However, even with the introduction of multi-gate devices, aggressive scaling down of IC dimensions has resulted in spacing challenges between gate structures and source/drain features, the contacts thereto, and the metallization lines connecting to said contacts. Device performance can be affected by these arrangements including affecting resistance of the devices. While existing interconnect structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIGS. 1A and 1B illustrate fragmentary plan view and cross-sectional views respectively of a semiconductor structure according to aspects of the present disclosure.

FIG. 2 is a flowchart illustrating a method of forming a semiconductor structure, according to various aspects of the present disclosure.

FIGS. 3A-12A illustrate fragmentary top views illustrating a layout of a device at various stages of fabrication in accordance with the method in FIG. 2, according to various aspects of present disclosure.

FIGS. 3B, 4B, 5B, 6B, 7B, 8B, 9B, 10B, 11B, 11D, 11F, 11G, 12B and 3C, 4C, 4D, 5C, 6C, 7C, 8C, 9C, 10C, 11C, 11E, 12C illustrate corresponding fragmentary cross-sectional views taken in a first direction and a second direction, respectively of a device at various stages of fabrication in accordance with the method in FIG. 2, according to various aspects of present disclosure. FIGS. 3D and 12D illustrate corresponding fragmentary cross-sectional views taken in the second direction of a device at various stages of fabrication in accordance with the method in FIG. 2, according to various aspects of present disclosure.

FIGS. 13, 14, and 15B illustrate fragmentary cross-sectional views of a various embodiments of a device, according to various aspects of present disclosure.

FIGS. 15A, 16A, 16B and 16C illustrate fragmentary top views of a various embodiments of a device, according to various aspects of present disclosure.

FIG. 17 illustrates a fragmentary plan view of a semiconductor structure and layout according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

As integrated circuit (IC) technologies progress towards smaller technology nodes, multi-gate metal-oxide-semiconductor field effect transistor (multi-gate metal oxide semiconductor field effect transistors (MOSFET), or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-channel transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A multi-channel transistor has a gate structure that can extend, partially or fully, around a channel region to provide access to the channel region on two or more sides. Because its gate structure surrounds the channel regions, such a transistor may also be referred to as a gate-all-around (GAA) transistor. The channel region may include nanowires, nanosheets, or other nanostructures and for that reasons, this transistor may also be referred to as a nanowire transistor or a nanosheet transistor. Any of these transistor structures may benefit from the present disclosure; while some illustrations are provided using FinFET structures aspects of the present disclosure apply equally to, for example, GAA or planar transistors.

The formation of interconnects to provide electrical connection to and among such transistors is not without challenges. For example, when providing an interconnection to a feature of a transistor, such as a gate, source or drain terminal, it is important to consider the conductive path between the transistor feature and the interconnect line that is connected thereto (e.g., signal or power lines). Interconnects include multiple levels to afford appropriate connection and routing of signals and one or more of these multiple levels are used to form the conductive path. In some implementations, a lower level of the interconnect is a device-level contact structure. A device-level contact structure is a conductive element formed on the transistor feature (e.g., source/drain). Above the device-level contact structure, a via may be provided that forms a conductive path to a first metal line, such as a power rail, formed on a first metallization layer, which is also referred to as a metal layer that comprises metal lines. The metal line provides a horizontal routing, and the via and device-level contact structure provide a routing that is, at least in part, vertical.

In some configurations, the conductive path from a metal line such as a power rail to the transistor feature (e.g., source/drain terminal) may be of a length that causes undesired increases in the resistance of the semiconductor device. The interconnect configuration (routing) can negatively affect both the contact resistance (Rc) and the sheet resistance (Rs). For example, a via between a contact structure and a power rail may be disposed are far away from the active region and the transistor feature to which the contact structure it is connected. Thus, the horizontal extension required of the contact structure from the transistor feature to via leads to high resistance (Rc and/or Rs) between the transistor feature and the metal line, e.g., power rail.

The present disclosure provides embodiments of a device having, and a process for forming, interconnect structures that in some implementations reduce the contribution of the interconnect structure to the resistance of the device. In some implementations, the interconnect structure includes a via that is non-linear in shape (e.g., wavy-shaped or undulating shape) in a plan view. The undulating shape via can improve Rc and Rs of the semiconductor device by reducing the length of path of the signal from the contact to the transistor terminal to the metal line and/or by increasing the surface area of contact between the via and under/overlying interconnect features. By increasing the landing area between the via and the underlying contact structure (e.g., device-level contact), contact resistance can be reduced. By increasing the contacting area between the via and the overlying metallization feature (e.g., metal line), contact resistance can be reduced. In some embodiments, providing the contact area without a barrier layer can also reduce resistance.

Also, in applying one or more of the aspects discussed in further detail below, the interconnect area can be increased without accompanying barrier layer thickness increases there by reducing contact resistance. Increasing the portion of the via that extends along the overlying metal layer (e.g., horizontally) can provide a sheet resistance reduction. The configuration can also, in some implementations, decrease the path length between the contact (e.g., source contact) and the power line, which can provide for a decrease in sheet resistance. By defining the shape of the via, a concave portion can be configured to further insulate the via from adjacent features such as other contact structures thereby possibly reducing leakage.

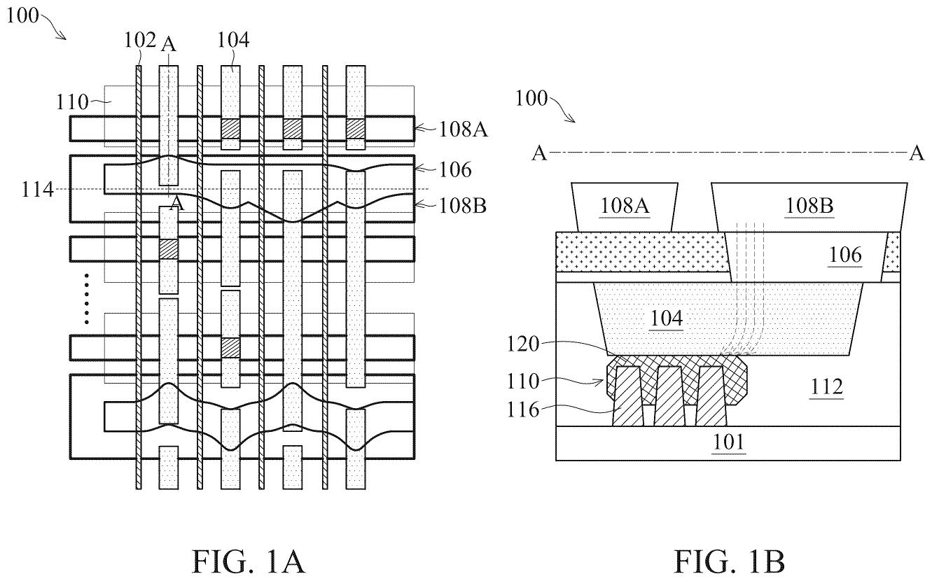

The various aspects of the present disclosure will now be described in more detail with reference to the figures. In that regard, FIGS. 1A and 1B are first presented to illustrate the top view and cross-sectional view respectively of fragmentary views of a device 100. FIG. 1B is a cross-sectional view taken along line A-A′, which is parallel the gate line 102. The semiconductor device 100 is merely an example according embodiments of the present disclosure and not intended to be limiting, beyond what is explicitly recited in the claims that follow.

The semiconductor device 100 is illustrative of a via 106 that has a shape that may be referred to as curvy, serpentine, sinuous or undulating in the top view as shown in FIG. 1A. The shape, referred to herein generally as undulating, refers to a deviation from a linear shape such as a rectangle having opposing linear, parallel sidewalls when viewed from the top view. While the undulating-shape of FIG. 1a is illustrated having an outline smoothly rising and filing in its outline (e.g., top view), the undulating-shape is not required to be smooth, curved, or even including as illustrated by the embodiments presented herein.

The undulating-shape via structure 106 vertically interposes and interconnects a first interconnect layer, contact 104—a device-level contact, and an overlying second interconnect layer 108—a metal layer, which includes at least components 108A and 108B, which may be coplanar horizontally extending metal lines. In the illustrated embodiment, the contact 104 interfaces a portion of an active region 110 here illustrated as including a source/drain feature 120 over a plurality of fins 116 extending from a substrate 101. The contact 104 interfaces a plurality of source/drain features 120, for example a single contact 104 extending in the y-direction of FIG. 1A interfaces a plurality of source/drain features along its length including for example, those disposed in different active regions 110. It is noted that the contact 104 may interface the source/drain feature 120 such that the bottom of the contact 104 is curved and interfaces lateral sides of the source/drain feature 120. The contact 104 may have a tapered short in the cross-section such as illustrated by the cut A-A′ of FIG. 1B. The contact 104, undulating-shape via structure 106, and the interconnect layer 108 are part of a multi-layer interconnect (MLI) structure that provides a conductive path to/from the transistor feature (source/drain). Each of the conductive features of the MLI has insulating materials 112 adjacent thereto to provide insulation around the conductive path.

The MLI structure of exemplary device 100 includes features that may be considered middle-end of-line (MEOL), however the application of the undulating-shape via structure is not limited thereto. IC manufacturing process flow is typically divided into front-end-of-line (FEOL), MEOL, and back-end-of-line (BEOL). FEOL generally encompasses processes related to fabricating IC devices, such as transistors including active region 110. MEOL generally encompasses processes related to fabricating contacts to conductive features (or conductive regions) of the IC devices, such as contacts to the gate structures and/or the source/drain features, such as contact 104. Contacts fabricated during MEOL such as contact 104 can be referred to as device-level contacts, metal contacts, and/or local interconnects. BEOL generally encompasses processes related to fabricating a MLI structure that interconnects IC features fabricated by FEOL and MEOL (referred to herein as FEOL and MEOL features or structures, respectively), thereby enabling operation of the IC devices. In the MLI, multiple metal lines and vias can be formed, for example, typically referred to as metal-0 (MO), metal-1 (M1), and so forth each with interposing vias. In some embodiments, undulating-shape via structures 106 may be formed at various levels of the MLI.

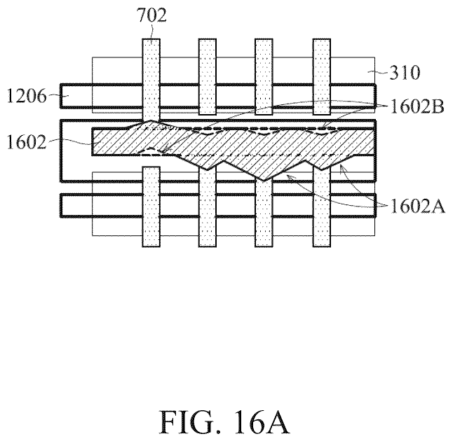

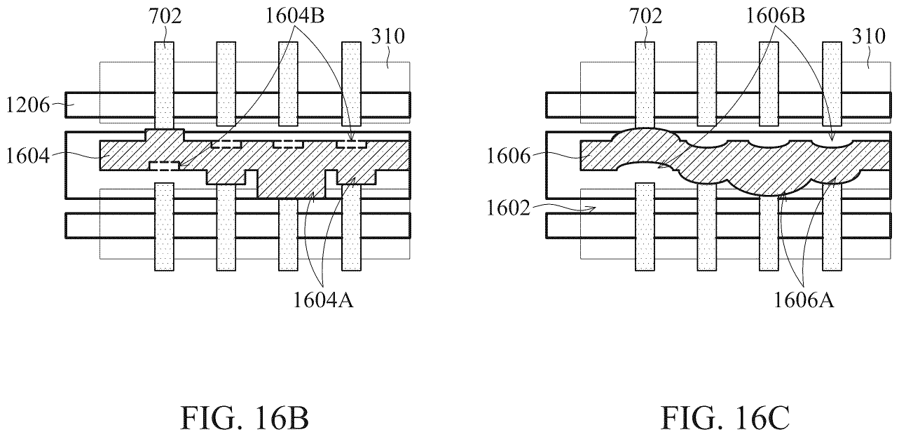

As discussed above, the via structure 106 exhibits an undulating-shape (also referred to as serpentine or sinuous or simply non-linear, in its top view, which is illustrated by its shape with respect to imaginary line 114, which is extending in the x-direction of FIG. 1A perpendicular to direction of the extension of a gate structure 102. The imaginary line 114 may extend collinear with a linear segment of a sidewall of the via structure 106. A linear via structure would have a substantially rectangular shape in the top view, including a first sidewall collinear with the line 114 across the distance of the linear via structure, and an opposing sidewall parallel to the line 114 across the distance of the linear via structure or in other words, the shape of a linear via structure in the plan view is defined by opposing linear, parallel sidewalls. In contrast, a non-linear or undulating-shape via structure 106 has a non-rectangular shape in the top view and includes a sidewall that varies in distance from the line 114 and an opposing sidewall that is, in at least one regions, non-parallel to the line 114. In an embodiment as illustrates, the undulating-shape via structure 106 has curvilinear or curvy sidewalls. The sidewalls extend such that the via structure includes “concave” portions (sidewalls extending toward the line 114) and “convex” portions (sidewalls extending away from line 114). The concave portions may also be referred to as indentations. The convex portions may also be referred to as protrusions. It is noted that the undulating-shape via structure 106 does not require curvilinear portions, but may also be defined with linear sidewalls that extend, in at least some portions, non-parallel to the line 114. See FIGS. 16A, 16B for contact structures having linear outlines in the top view; FIG. 16A illustrates an example of linear outline or sidewalls transverse to line 114 and FIG. 16B an example of linear outline or sidewalls orthogonal to the line 114. In that effect, the “concave” and “convex” portions are not required to be defined by curvilinear outlines.

In some implementations, the undulating shape of the via 106, an in particular the location of the convex and/or concave portions, is determined and provided such that convex portions are provided adjacent a contact structure 104 to which the via 106 has an electrical connection by interfacing in a landing region. In other words, the convex portion increases the landing region in comparison with a linear via structure. And the undulating shape of the via 106 is selected such that concave portions are provided adjacent structures (e.g., contact structures 104) to which the via is not interconnected, but electrically insulated from. In other words, the concave portions move the via 106 further from contact structures 104 that the via 106 is to be insulated from.

As illustrated by the dashed lines of FIG. 1B, a conductive path from the metal layer 108B to the source/drain feature 120 is substantially vertical. In other words, the configuration of the interconnect allows a signal to travel from metal line 108B in a vertical direction through via 106 (e.g., a convex portion), to the device-level contact 104. In an embodiment, the area of the source-side via 106 has an area of approximately 1.1 to 50 times greater than the drain-side via 107 (e.g., as measured from a top view). In an embodiment, the source-side via 106 has a thickness (e.g., vertical distance in FIG. 1B) of between about 0 nanometers (nm) and 100 nm. In an embodiment, the source-side via 106 has a length (e.g., horizontal distance in FIG. 1A) of approximately 200 μm, in some embodiments, the length is greater than 200 μm. For example, the via 106 may extend a distance along the overlying metallization layer (e.g., M0 or 108B) of approximately 200 μm, or more. As discussed below, the metal of the via 106 and via 107 may be formed in a single deposition (e.g., have a same composition), may be formed by a bottom-up deposition process without a barrier layer or some combination thereof.

Various aspects of the device 100 and features thereof are discussed with respect to the embodiments illustrated in the following illustrations. The various aspects of the present disclosure will now be described in more detail with reference to methods for forming devices.

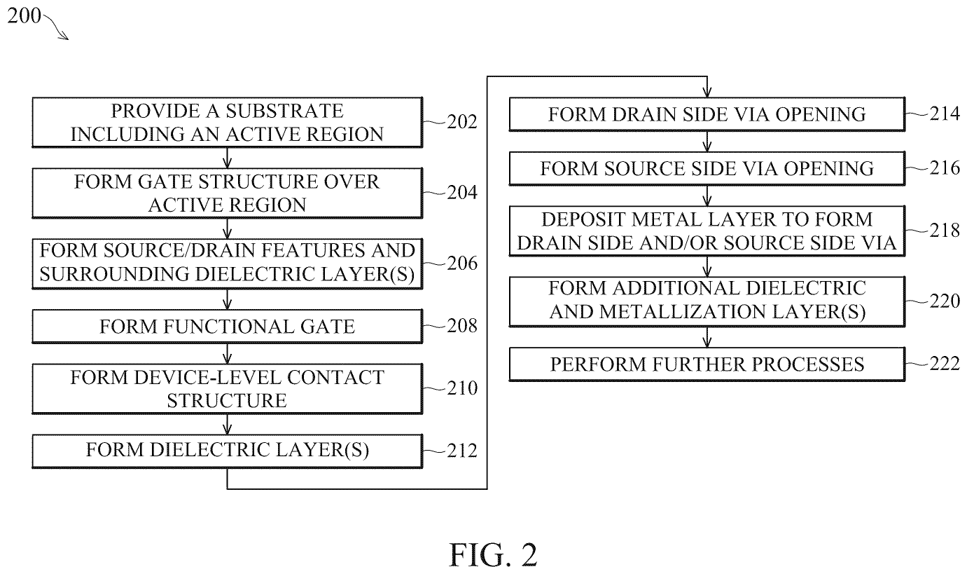

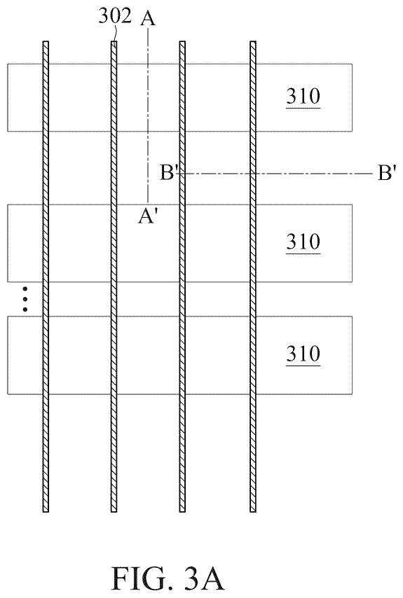

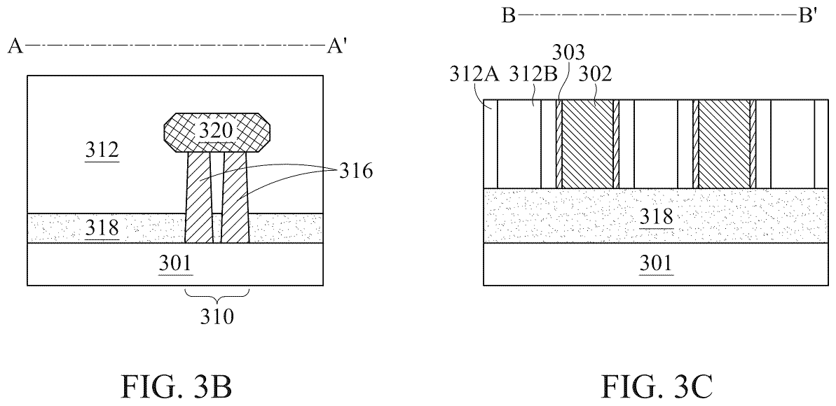

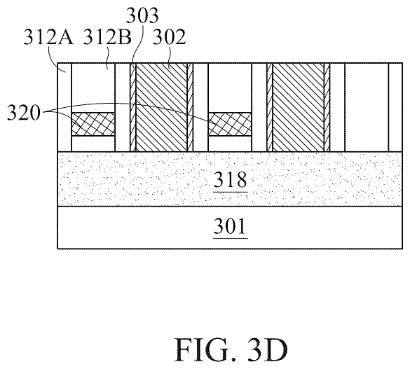

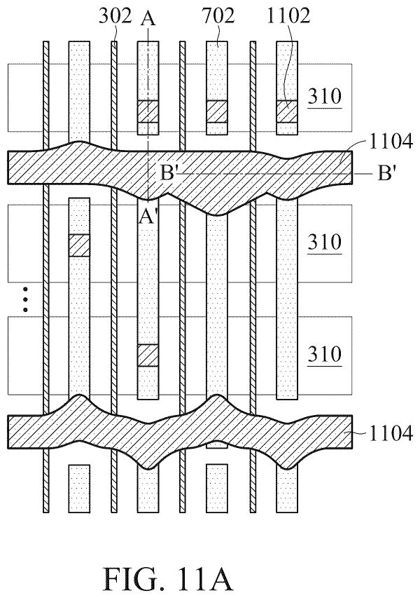

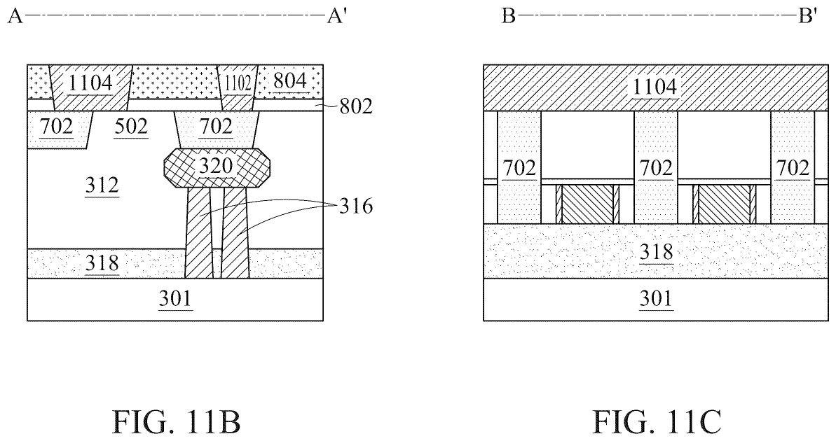

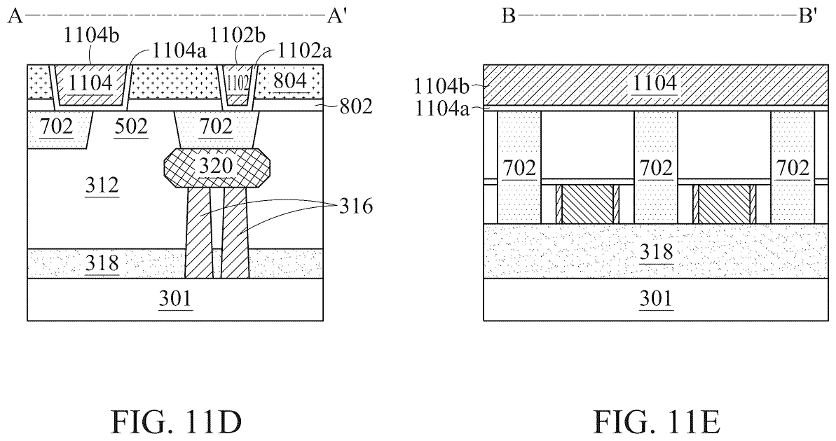

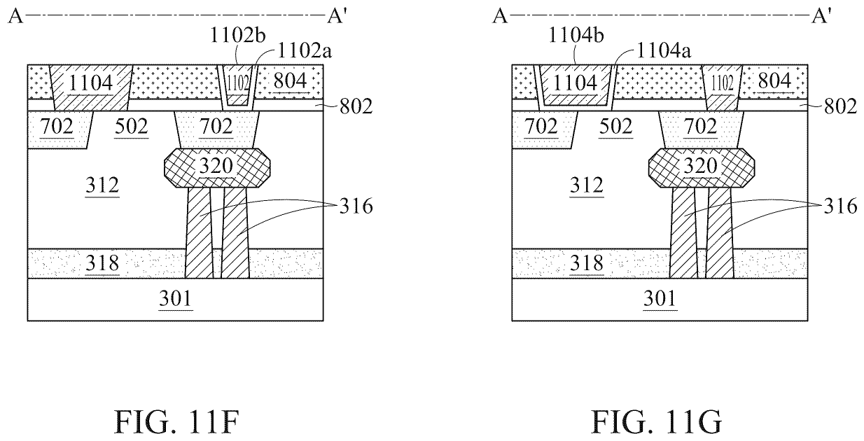

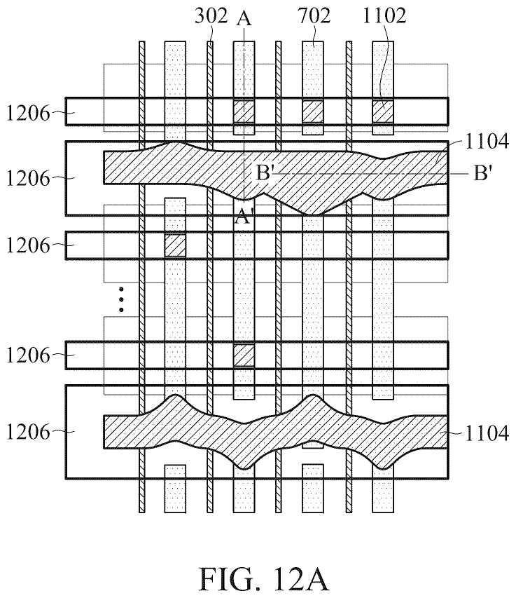

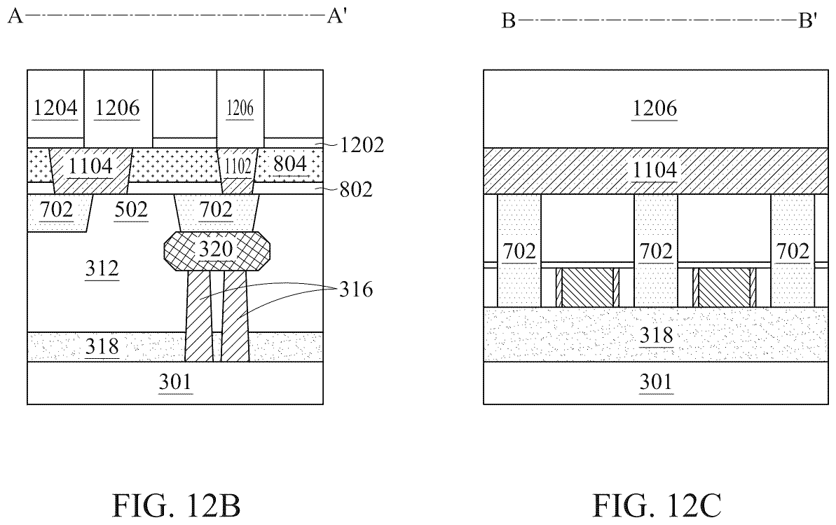

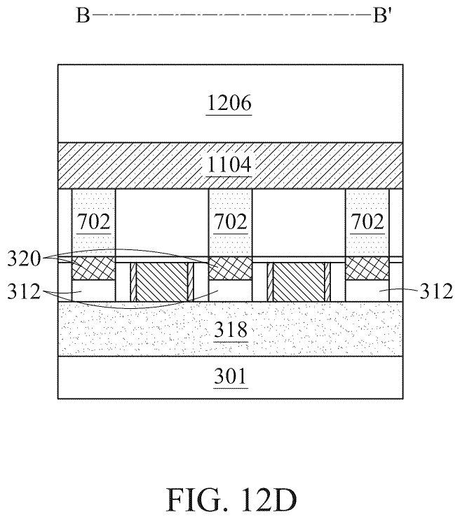

In that regard, FIG. 2 is a flowchart illustrating a method 200 of forming a semiconductor device according to embodiments of the present disclosure. Method 200 is merely an example and is not intended to limit the present disclosure to what is explicitly illustrated in method 200. Additional steps can be provided before, during and after the method 200, and some steps described can be replaced, eliminated, or moved around for additional embodiments. Not all steps are described herein in detail for reasons of simplicity. Method 200 is described below in conjunction with FIGS. 3A-12A, which are fragmentary top or plan views of a device 300, FIGS. 3B-12B, which are a fragmentary cross-sectional views of a device 300 in a first cross-sectional cut and at different stages of fabrication according to embodiments of the method 200 in FIG. 2; FIGS. 3C-12C and 4D, which are a fragmentary cross-sectional views of the device 300 in a second cross-sectional cut and at different stages of fabrication according to embodiments of the method 200 in FIG. 2; and FIGS. 3D and 12D, which are fragmentary cross-sectional views of the device 300 in a cross-sectional cut parallel that of FIGS. 3C and 12C respectively. FIGS. 11D, 11E, 11F, and 11G provide different embodiments of metallization forming vias. Throughout the present disclosure, like reference numerals denote like features unless otherwise expressly excepted.

For illustration purposes, the figures including FIGS. 3B-12B depict processes and structures for a FinFET where a source/drain feature is formed on a fin-shaped active region (i.e., a fin) or fins. However, the present disclosure is not so limited and it should be understood that the various embodiments of the present disclosure may be similarly applied to other structures. Further, the number of fins associated with the source/drain feature is exemplary only and may be more of less than as illustrated. For example, while some illustrations provide a merged source/drain over adjacent fins, in other embodiments the source/drain feature may extend over a single fin.

Referring now to FIGS. 2 and 3A, 3B, 3C, and 3D, the method 200 includes a block 202 where a substrate including an active region is received. In some embodiments, the received substrate includes FEOL processes performed to form transistor elements. Referring to FIGS. 3A, 3B, 3C, and 3D, a substrate 301 that includes a plurality of fins 316 is received. The fin(s) 316 forms an active region 310 of the device 300. The cross-sectional view of the device 300 in FIG. 3B illustrates two exemplary fins 316 extending from the substrate 301.

In some embodiments, the substrate 301 includes silicon (Si). Alternatively or additionally, substrate 301 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 301 includes one or more group III-V materials, one or more group II-IV materials, or combinations thereof. In some implementations, the substrate 301 is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. While not explicitly shown, the substrate 301 can include various doped regions configured according to design requirements of the desired semiconductor device. The various doped regions can be formed directly on and/or in substrate 301 by doping with p-type dopants or n-type dopants to provide a p-well structure, an n-well structure, or combinations thereof. Example p-type dopants may include boron (B), boron difluoride (BF₂), other p-type dopant, or combinations thereof. Example n-type dopants may include phosphorus (P), arsenic (As), other n-type dopant, or combinations thereof. An ion implantation process, a diffusion process, and/or other suitable doping process can be performed to form the various doped regions.

The fins 316, which extend lengthwise along the X direction of the active region 310 of FIG. 3A, may be formed from the substrate 301 or an epitaxial layer deposited on the substrate 301. When an n-type FinFET is desired, such an epitaxial layer may be a silicon (Si) layer. When a p-type FinFET is desired, such an epitaxial layer may be a silicon germanium (SiGe) layer. In some implementations, to form the fins 316, the substrate 301, alone or together with the epitaxial layer (if formed), undergoes photolithography processes and etch processes to pattern the fins 316. In some instances, patterning of the fins 316 may include use of double-patterning or multi-patterning processes. At times, double-patterning or multi-patterning processes combine photolithography and self-aligned processes, allowing patterns to be created that have, for example, pitches smaller than what is otherwise obtainable using a single, direct photolithography process.

As shown in FIG. 3B, the fins 316 are spaced apart from one another along the Y direction by an isolation feature 318. The isolation feature 318 may also be referred to as a shallow trench isolation (STI) feature 318. In an example process, a dielectric material for the isolation feature 318 is first deposited over the substrate 301, filling the trenches between fins 316 with the dielectric material. In some embodiments, the dielectric material may include silicon oxide, silicon oxynitride, fluorine-doped silicate glass (FSG), a low-k dielectric, combinations thereof, and/or other suitable materials. In various examples, the dielectric material may be deposited by a CVD process, a flowable CVD (FCVD) process, spin-on coating, and/or other suitable process. The deposited dielectric material is then thinned and planarized, for example by a chemical mechanical polishing (CMP) process, until top surfaces of the fins 316 are exposed. The planarized dielectric material is further recessed or etched back by a dry etching process, a wet etching process, and/or a combination thereof to form the isolation feature 318. In some embodiments represented in FIG. 3B, at least a portion of each of the fins 316 rises above the isolation feature 318.

Continuing to refer to FIGS. 2 and 3A, 3B, 3C, and 3D, a gate structure 302 is disposed over a channel region of the active area 310, which are fins 316. In an implementation, the gate structure 302 is first formed as a dummy gate structure, which is subsequently replaced by a functional gate structure. The gate structure 302 is formed over a channel region of the fin 316. In some instances, the dummy gate structure includes a dummy gate dielectric layer and a dummy gate electrode, such as polysilicon. Photolithography processes and etching processes may be used to pattern the dummy gate dielectric layer and dummy gate electrode layer into the dummy gate stacks to form the gate structure 302 that extends in the y-direction of FIG. 3A, which is perpendicular to the direction that the active region 310 and its fins 316 extend. The region of the fins 316 under the gate structures 302 define a channel region, with the adjacent regions not underlying a gate structure 302 providing source/drain areas.

Gate spacers 303 may be formed on sidewalls of the gate structures 302. In some embodiments, the gate spacers 303 may include silicon carbonitride, silicon oxycarbide, silicon oxycarbonitride, silicon nitride, and/or other suitable materials and may be deposited using suitable processes such as CVD. In some implementations, the gate spacers 303 include any suitable low-k dielectric material.

Referring to FIGS. 2 and 3A, 3B, 3C, and 3D, method 200 includes a block 206 where source/drain features 320 are formed over source/drain regions of the active region. In some implementations, the source/drain features 320 are formed on the fins 316, in the fins 316, and/or in recesses formed within the fins 316 of the active region. In an embodiment, the source/drain features 320 are formed on fins 316 for example by epitaxial growth from a seed of the fin 316 surface. The source/drain features 320 be also formed in recesses within the fin 316, again by such processes such as epitaxial growth. To that effect, block 206 may include recessing of the source/drain regions of the fin 316 to form source/drain recesses, and depositing the source/drain features 320 in the source/drain recesses. The recesses may be formed by an anisotropic etch process. An example anisotropic etch process is a dry etch process that includes use of a fluorocarbon (e.g., CF₄, SF₆, NF₃, CH₂F₂, CHF₃, and/or C₂F₆), a chlorine-containing gas (e.g., Cl₂, CHCl₃, CCl₄, and/or BCl₃), oxygen (O₂), hydrogen (H₂), argon (Ar), or a combination thereof. The source/drain features 320 are epitaxially deposited in the source/drain recesses of the fin 316, or alternative on the fin 316, using a suitable technique, such as vapor-phase epitaxy (VPE), ultra-high vacuum CVD (UHV-CVD), a cyclic deposition and etching (CDE) process, molecular beam epitaxy (MBE), and/or other suitable processes. Depending on the conductivity of the desired device, the source/drain features 320 may be n-type or p-type. When the desired device is n-type, the source/drain features 320 may be phosphorus-doped silicon (Si:P) or arsenic-doped silicon (Si:As). When the desired device is p-type, the source/drain features 320 may be boron-doped silicon germanium (SiGe:B).

Continuing to refer to FIGS. 2 and 3A, 3B, 3C, and 3D, method 200 at block 208 continues to deposit dielectric layer(s) over the source/drain features and adjacent the gate structure. The dielectric layer is illustrated as layer 312. In some implementations, block 206 includes dielectric layers including a first dielectric layer (e.g., contact etch stop layer (CESL)) 312A and an interlayer dielectric (ILD) layer 312B. In some implementations, the CESL 312A is conformally deposited over the source/drain features 320, and on at least one gate spacer layer 303. In some embodiments, the CESL 312A may be deposited using CVD or ALD and may include silicon nitride or silicon oxynitride. After the deposition of the CESL 312A, the ILD layer 312B is deposited over the CESL 312A. In some implementations, the ILD layer 312B may be deposited using CVD, FCVD, spin-on coating, or a suitable deposition method. The ILD layer 312B may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. After the deposition of the CESL 312A and the ILD layer 312B, a planarization process, such as a chemical mechanical polishing (CMP) process, is performed until top surfaces of the gate structure 302, and the ILD layer 312B are coplanar.

It is noted that the cross-section along line B-B′ is drawn through the isolation region between active regions 310. In an embodiment, a cross-sectional cut parallel to B-B′ may be taken along an edge of an isolation region 318 and the active regions 310, in such a cross-sectional view an edge of the source/drain feature 320 that lies over isolation layer 318. FIG. 3D is illustrative and this applies equally to the discussion below.

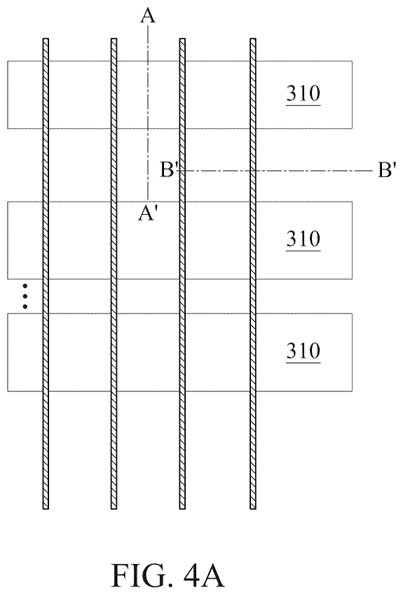

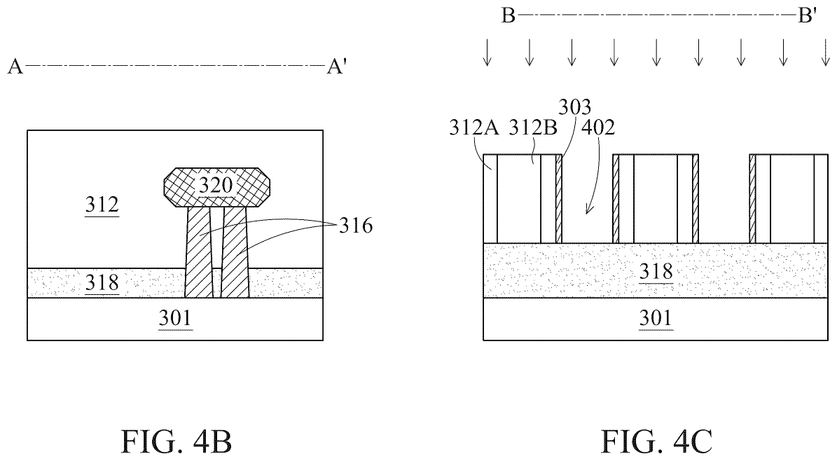

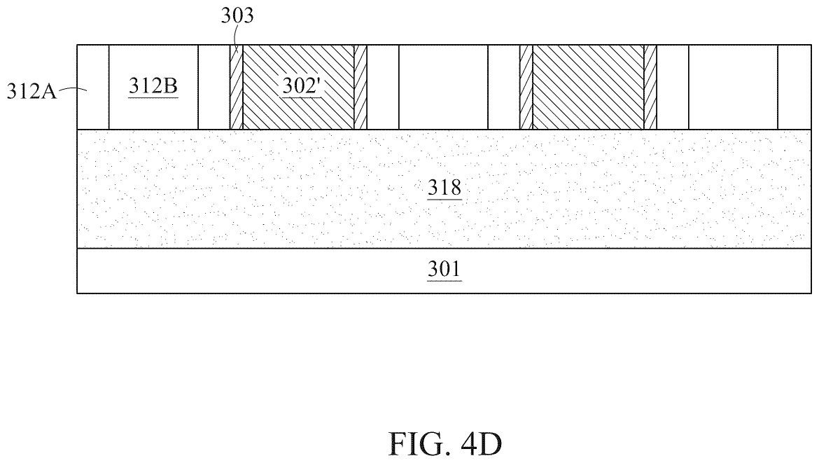

Referring to FIGS. 2 and 4A, 4B, 4C, and 4D in block 208 of the method 200, the gate structure of block 204 may be replaced with a replacement gate structure suitable for the functional device. In other implementations, the process is a gate-first process and the gate structure of block 204 remains in the device. In an embodiment, an etching process may be performed to remove dummy gate structures 302 to form gate trenches 402. The etching process may include one or more iterations of various etching techniques, such as wet etching, dry etching, RIE, and/or other suitable etching processes.

Referring to FIG. 4D, the gate trenches are filled with a functional gate structure 302′. The forming of the functional gate structure 302′ begins by forming a gate dielectric layer (not separately labeled) in the gate trench. The gate dielectric layer may include an interfacial layer and a high-k dielectric layer. In some instances, the interfacial layer may include silicon oxide. The high-k dielectric layer is formed of dielectric materials having a high dielectric constant, for example, greater than a dielectric constant of silicon oxide (k≈3.9). Exemplary high-k dielectric materials for the high-k dielectric layer include hafnium oxide, titanium oxide, hafnium zirconium oxide, tantalum oxide, hafnium silicon oxide, zirconium silicon oxide, lanthanum oxide, aluminum oxide, yttrium oxide, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material.

A gate electrode of the gate structure 302′ is then formed over the gate dielectric layer. The gate electrode may include multiple layers, such as work function layers, gluc/barrier layers, and/or metal fill (or bulk) layers. A work function layer includes a conductive material tuned to have a desired work function (such as an n-type work function or a p-type work function), such as n-type work function materials and/or p-type work function materials. P-type work function materials include TiN, TaN, Ru, Mo, Al, WN, ZrSi₂, MoSi₂, TaSi₂, NiSi₂, WN, other p-type work function material, or combinations thereof. N-type work function materials include Ti, Al, Ag, Mn, Zr, TiAl, TiAlC, TaC, TaCN, TaSiN, TaAl, TaAlC, TiAlN, other n-type work function material, or combinations thereof. A glue/barrier layer can include a material that promotes adhesion between adjacent layers, such as the work function layer and the metal fill layer, and/or a material that blocks and/or reduces diffusion between gate layers, such as such as the work function layer and the metal fill layer. For example, the glue/barrier layer includes metal (for example, W, Al, Ta, Ti, Ni, Cu, Co, other suitable metal, or combinations thereof), metal oxides, metal nitrides (for example, TiN), or combinations thereof. A metal fill layer can include a suitable conductive material, such as aluminum, copper, tungsten, ruthenium, titanium, a suitable metal, or a combination thereof. In some implementations, a metal capping layer such as aluminum, tungsten, cobalt, ruthenium, titanium, a suitable metal, combinations thereof, and/or other suitable materials is formed on the metal fill layer.

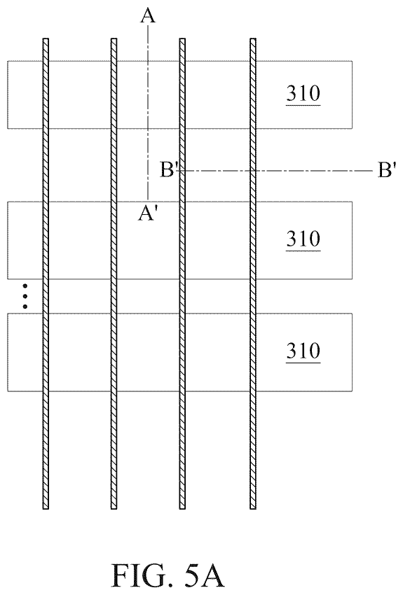

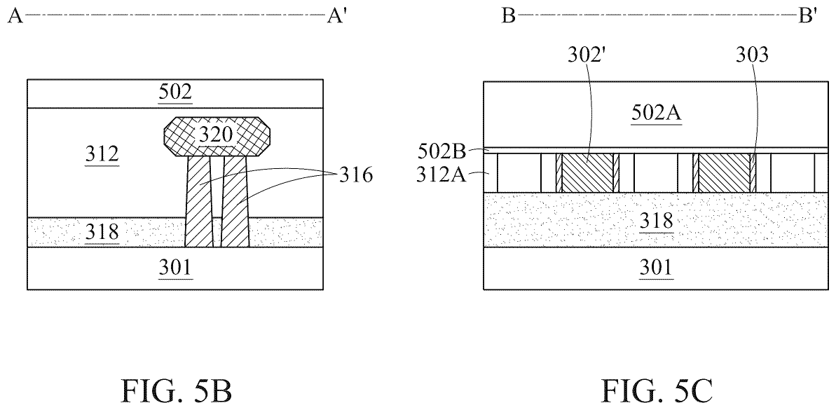

Referring to FIGS. 5A, 5B, and 5C, dielectric layers are formed over the gate structure 302′. In some implementations, the dielectric layers including a first dielectric layer (e.g., bottom contact etch stop layer (CESL)) 502B and an interlayer dielectric (ILD) layer 502A collectively referred to as dielectric 502. In an embodiment, the dielectric layer 502B includes silicon nitride and the dielectric layer 502A includes a silicon oxide based layer such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

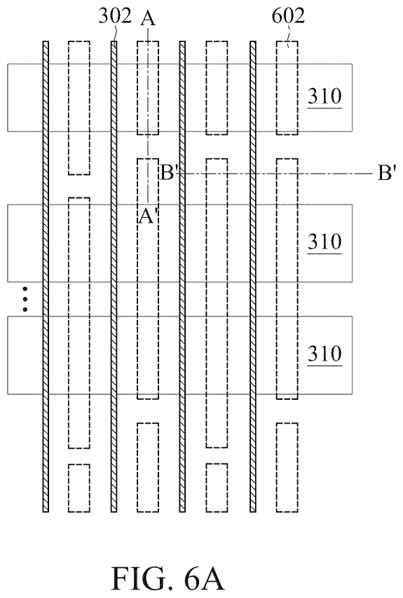

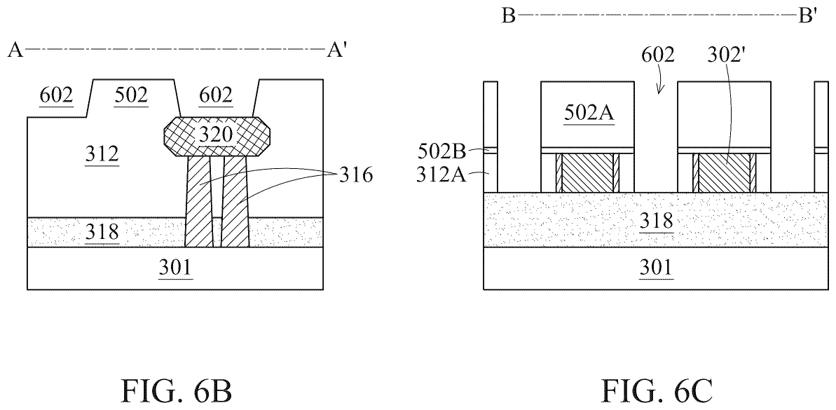

Referring to FIGS. 2 and 6A, 6B and 6C, method 200 includes a block 210 where device-level contact structures are formed. The device-level contacts include contacts to transistor features such as the source/drain features and/or the gate structures of the device. In some implementations, block 210 begins by selectively recessing the ILD layer 312B and the dielectric layers 502 to form trenches 602. The trenches 602 expose a top surface of the transistor feature (e.g., source/drain feature 320) to which a device-level contact is desired. In some embodiments, the composition of the ILD layer 312B is different from those of the CESL 312A, the gate spacer 303, and the gate structure 302′ allowing for a selective etch to form the trenches 602. In some embodiments, the dielectric layers 502 and ILD layer 312B may be recessed by using a dry etch, a wet etch, or a combination thereof. An example dry etching process may include use of a fluorocarbon (e.g., CF₄, SF₆, NF₃, CH₂F₂, CHF₃, and/or C₂F₆), oxygen (O₂), hydrogen (H₂), argon (Ar), or a combination thereof. An example wet etch process may include use of buffered hydrofluoric acid (BHF, a mixture of hydrofluoric acid and ammonium fluoride).

In particular, recessing of the dielectric layers 502 and ILD layer 312B forms trenches 602 exposing the source/drain feature 320. Concurrently or separately portions a trench may be formed over the gate structure 302′ However, such trenches may not be aligned with the trenches 602 to the source/drain features 320 and thus, the gate level contacts are not illustrated. The trenches 602 may expose the source/drain features 320 for both the source side and the drain side, or in other embodiments may expose only a single side (e.g., source or drain) of the transistors. As illustrated, the trenches 602 extend a distance over the active regions and also the isolation regions, thereby in some regions the trenches 602 expose the isolation layer 318 that extends between active regions (e.g., between fins).

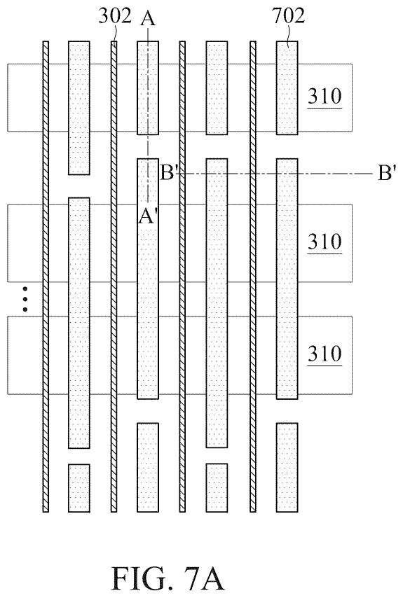

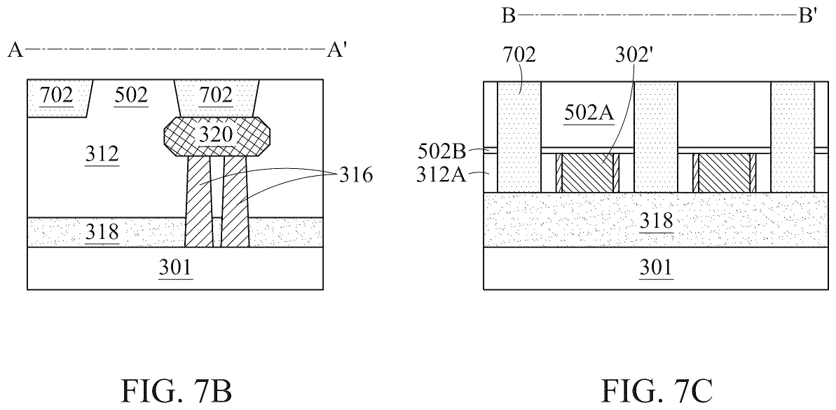

Referring to FIGS. 2 and 7A, 7B and 7C, block 210 proceeds to form the device-level contact structures in the trenches, which includes contacts 702 being formed by depositing conductive materials in the trenches 602 over the source/drain features 320. The contact 702 may be substantially similar to contact 104 of FIGS. 1A and 1B. In an embodiment, the contact 702 at the left of the fragmentary view of FIG. 7B may be a source-side contact such as illustrated in FIGS. 1A and 1B. In an embodiment, the contact 702 at the right of the fragmentary view of FIG. 7B may be a drain-side contact. Both contacts 702 are referred to as device-level contacts.

In some implementations, a silicide layer is formed from the deposited conductive material, e.g., a metal fill layer (and/or any barrier layer discussed below), and the source/drain feature 320. In some instances, the silicide layer may include titanium silicide, cobalt silicide, nickel silicide, tantalum silicide, tungsten silicide, and/or other silicide compositions including germano-silicides. Above the silicide, the deposited metal remains. Together the silicide and metal(s) are referred to as source/drain contacts 702. In some implementations, the source/drain contacts 702 include a barrier layer. The barrier layer may include a metal or a metal nitride, such as a titanium nitride, cobalt nitride, nickel, tungsten nitride. The metal fill layer may be cobalt. Other example materials for the contacts 702 may include tungsten, ruthenium, nickel, copper, and/or other suitable materials. In some embodiments, the metal fill layer may be deposited over the barrier layer.

In some implementations, the deposition of conductive material(s) to form the contacts 702 creates an interface layer between the conductive material and the dielectric layer 312. In an embodiment, the interface layer includes a composition comprising one or more elements from the dielectric layer(s) 312 such as CESL 312A and one or more elements from the conductive material of the contacts 702.

After depositing the conductive material(s), a CMP process may remove excessive materials and provide a planar surface such as illustrated in FIGS. 7B, 7C. The top surface of the contact 702 provides a landing region onto which subsequent interconnect features are formed and/or have a direct interface.

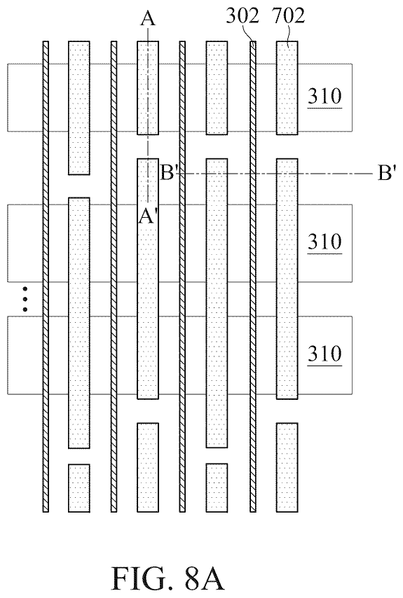

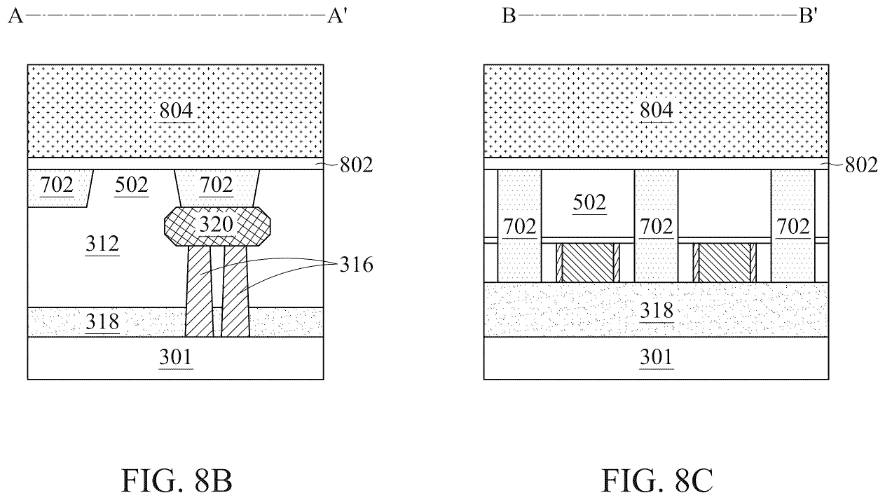

Referring to FIGS. 2 and 8A, 8B and 8C, method 200 includes a block 212 where additional dielectric layers are formed on the device. In some implementations, the dielectric layers include an etch stop layer 802 and an ILD layer 804. In an embodiment, the etch stop layer 802 is silicon nitride (SiN). Other examples of dielectric materials for the etch stop layer 802 include silicon oxide, silicon, silicon carbide, silicon carbonitride, and/or other materials known in the art. In an embodiment, the ILD layer 804 is SiO₂. Other example materials for the ILD layer 804 include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 804 and/or etch stop layer 802 may be deposited by a CVD process, a flowable CVD (FCVD) process, a spin-on coating process, or other suitable deposition technique.

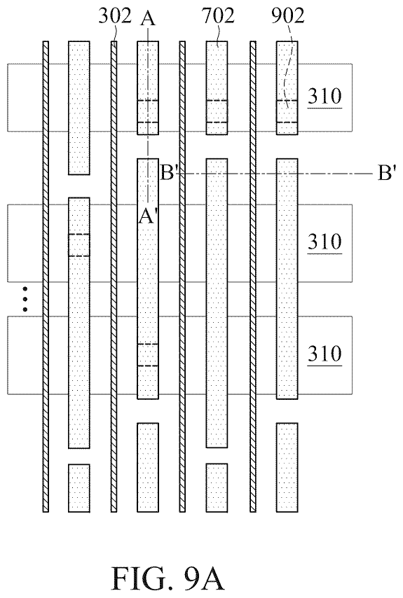

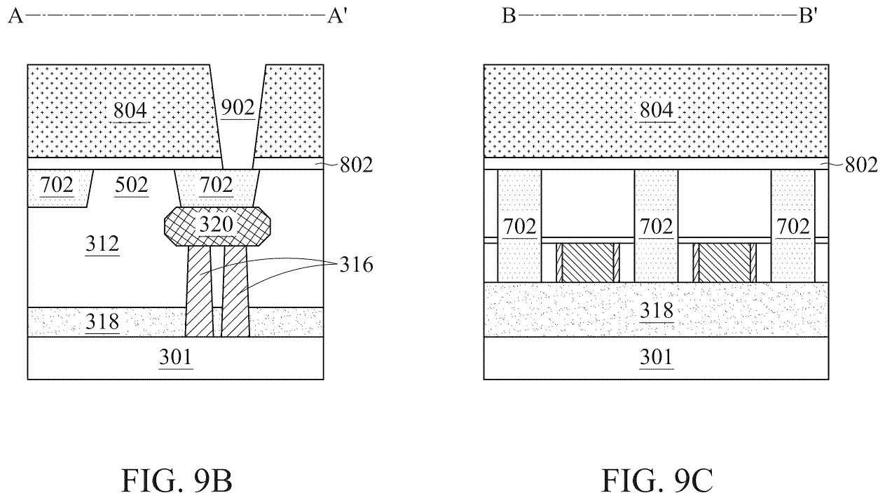

Referring to FIGS. 2 and 9A, 9B and 9C, method 200 includes a block 214 where a first via opening or hole associated with a first device feature is formed. A first via opening 902 is formed. The first via opening defines an opening where a first via structure is to be formed, the first via structure contacting a device-level contact associated with a first device feature. In some implementations, the first via opening is associated with the drain of a transistor and is referred to as a drain-side via opening. A plurality of first via openings are formed each to a respective transistor feature (e.g., drain). That is, in some implementations, block 214 includes forming a drain-side via opening that exposes a drain-side device-level contact. For example, a top surface of a drain-side device-level contact 702 is exposed as illustrated in FIG. 9B. And when the drain-side via opening is filled with conductive materials, a drain-side via directly contacts the device-level contact structure 702 formed on the drain feature of a transistor thereby providing an electrical path to/from the drain.

In some implementations in forming the via opening of block 214, a masking layer is formed over the ILD layer 804. The masking layer may include a hard mask layer and/or a photosensitive layer. The masking layer is patterned to define an opening (e.g., defining the region 902) over the ILD layer 804 at the location of the desired via. While providing the masking clement, an etching process removes the ILD 804 and etch stop layer 802 to form an opening or hole 902 over the drain-side device-level contact 702. The etching process may include an anisotropic etching process such as a dry etching process. In some embodiments, a tapered via hole is formed. That is when viewed in the cross-sectional view (e.g., FIG. 9B), two inverted tapered sidewalls that decrease in spacing along the depth of the opening 902 are provided. As illustrated in FIG. 9A, in an embodiment, the opening 902 is substantially rectangular, e.g., square, from a plan view.

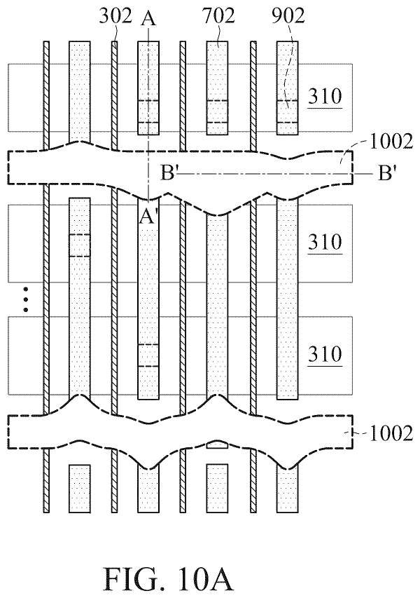

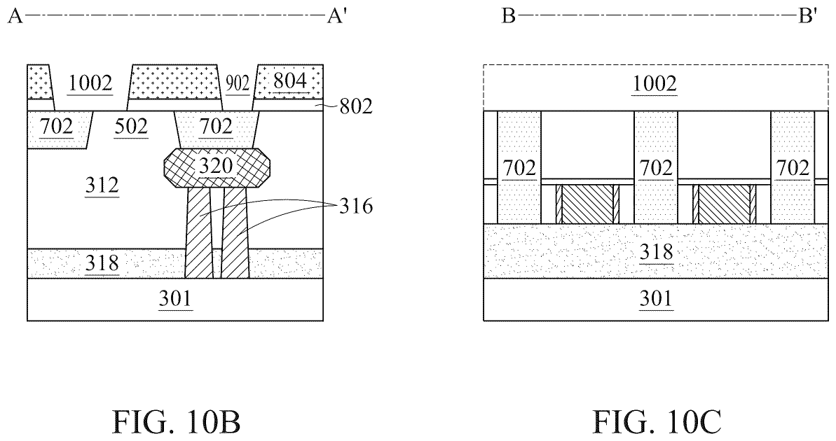

Referring to FIGS. 2 and 10A, 10B and 10C, method 200 includes block 216 where a second via opening associated with a second device feature is formed. The second via opening defines a position for a second via structure that is to be formed within the second via opening, the second via structure contacting a device-level contact associated with a second device feature. In some implementations, the second via opening is associated with the source terminal of a transistor. In some embodiments, the via opening 1002 is provided, where the second via opening 1002 exposes a portion of the source-side contact 702. That is, in some implementations, block 214 includes forming a source-side via opening 1002 that exposes a source-side device-level contact (or portion thereof) 702. And when the source-side via opening is filled with conductive materials, a source-side via directly contacts the device-level contact structure formed on the source of a transistor thereby providing an electrical path to/from the source.

In some implementations in forming the via opening of block 216, a masking layer is formed over the ILD layer 804. The masking layer may include a hard mask layer and/or a photosensitive layer. The masking layer is then patterned to form an opening over the ILD layer 804 at the location of the desired via. While providing the masking clement, an etching process removes the ILD 804 and etch stop layer 802 to form an opening 1002 over the drain-side device-level contact 702. The etching process may include an anisotropic etching process such as a dry etching process. In some implementations, block 216 is performed prior to block 214. In some implementations, block 216 is performed concurrently with block 214 (e.g., a single masking clement defines both the opening 902 and the opening 1002).

When viewed from a cross-sectional plane such as provided in FIG. 10B, the via opening 1002 may be tapered from top to bottom. That is, when viewed from a cross-sectional cut, the opening 1002 has two inverted tapered sidewalls that decrease in spacing along the depth of the via opening.

The via opening of block 216 from a plan view is an opening extending as a strip such that its length in the x-direction is substantially greater than its length in the y-direction of FIG. 10A. The via opening 1002 is also an undulating-shape in its top view, as is illustrated in FIG. 10A. The undulating-shape opening 1002 as illustrated has curvilinear or curvy sidewalls, though as discussed above with reference to via 106, the shape is not limited thereto. The undulating-shape opening 1002 includes openings having sidewalls that are linear, but a given sidewall may not be collinear across the strip providing a non-linear shape, which is referred to herein as an undulating-shape. In other words, in embodiments, the via opening 1002 is not a rectangular shape.

In some implementations, the undulating-shape of the opening is defined such that convex portions are provided adjacent/above the contact structure 702 to expose a greater portion of the contact structure 702. In some implementations, the concave portions of the undulating-shape are provided adjacent/above the contact structure 702 to which the via formed in the opening 1002 is not to be interconnected.

In some implementations, the undulating shape is defined by the masking element (e.g., resist and/or hardmask) having curvilinear sidewalls. In other implementations, the masking element may provide linear sidewalls defining convex and concave regions, which form curvilinear or curved sidewalls of the opening 1002 due to the etch biasing.

Referring to FIGS. 2 and 11A, 11B, and 11C, method 200 includes a block 218 where metallization is formed in the via openings of block 216 and/or 214 to form respective via structures. In the illustrated embodiments, the via 1102 is formed in opening 902. And the via 1104 is formed in opening 1002. The via 1102 may be a drain-side via interfacing directly with the contact structure 702 that connects to a drain terminal of a transistor (e.g., source/drain feature 320). The via 1104 may be a source-side via interfacing directly with the contact structure 702 that connects to a source terminal of a transistor (e.g., source/drain feature 320).

In an embodiment, the metallization deposited to form the via 1102 and/or the via 1104 do not include a liner or adhesion layer. Thus, in some implementations, the via 1102 and/or via 1104 include a contiguous metallization from a first sidewall to a second sidewall. Exemplary embodiments of this configuration are illustrated in FIGS. 11B, 11C.

In an embodiment, metallization may be formed in via opening 902 and via opening 1002 concurrently. Thus, in an embodiment, the drain-side via 1102 and source-side via 1104 may include the same metal material(s). In an embodiment, metallization may be formed in via opening 902 and via opening 1002 separately. Thus, in some embodiments, drain-side via 1102 and source-side via 1104 may include different materials. In some embodiments, one of the drain-side via 1102 and the source-side via 1104 includes additional layers (e.g., liner layers) and the other one of the drain-side via 1102 and the source-side via 1104 omits additional layers (e.g., lacks liner layer).

In an embodiment, the metallization formed in via opening 902 and/or via opening 1002 is formed by a bottom-up metal deposition process. In a further embodiment, the bottom-up metal deposition process does not include forming a barrier layer. In some implementations, the bottom-up metal deposition process includes at least partially or substantially filling the opening with a metal by introducing a bottom-up gas phase deposition process that deposits the metal on a conductive surface (e.g., contact 702). In some implementations, the dielectric layer surfaces (e.g., 312) are hindered from deposition (e.g., by creation of surface properties such as hydrophobic functional groups) such as by surface treatments.

In an embodiment, the metal of the vias 1102 and/or 1104 is tungsten (W). Other possible metals include ruthenium (Ru), cobalt (Co), aluminum (Al), iridium (Ir), iridium (Ir), rhodium (Rh), osmium (Os), palladium (Pd), platinum (Pt), nickel (Ni), copper (Cu), molybdenum (Mo), and other suitable conductive materials including alloys thereof. As indicated above, in some implementations, the vias 1102 and/or 1104 do not include a liner layer providing the possible metals to interface directly the contacts 702. After the deposition of the metal(s), a chemical mechanical polish (CMP) process may be performed to remove materials over the ILD 804.

FIGS. 11D, 11E and 11F illustrate embodiments as discussed above. In FIG. 11D, the vias 1102 and 1104 each include a liner layer, in particular, a liner layer 1102a and a metallization layer 1102b form via 1102 and liner layer 1104a and a metallization layer 1104b form via 1104. In some embodiments, the liner layers 1102a and 1104a may be a multi-layer structure including Ti and TiN. In an embodiment, the metallization layers 1102b and 1104b may include tungsten, or other metals discussed above. FIG. 11E illustrates the cross-section along B-B′. In FIG. 11F, the vias 1102 include a liner layer, in particular, a liner layer 1102a and a metallization layer 1102b. In some embodiments, the liner layer 1102a may be a multi-layer structure including Ti and TiN. The via 1104 may be formed without a liner layer. In an embodiment, the metallization layers 1102b and 1104b may include tungsten, or other metals discussed above. The corresponding B-B′ cut to FIG. 11F is illustrated by FIG. 11C. In FIG. 11G, the vias 1104 include a liner layer, in particular, a liner layer 1104a and a metallization layer 1104b. The corresponding B-B′ cut is illustrated by FIG. 11E. In some embodiments, the liner layer 1104a may be a multi-layer structure including Ti and TiN. The via 1102 may be formed without a liner layer.

The source-side via 1104 may be substantially similar to the source-side via 106 of the device 100 described above with reference to FIGS. 1A and 1B.

Referring to FIGS. 2 and 12A, 12B, 12C, and 12D, method 200 includes a block 220 where additional dielectric layers and a metallization layer such as a metal routing layer are formed on the device. In some implementations, an etch stop layer 1202 and an ILD layer 1204 are formed. The etch stop layer 1202 may be formed of silicon nitride, silicon oxide, silicon, silicon carbide, silicon carbonitride, and/or other materials known in the art. The etch stop layer 1202 may be different than, or the same as, the etch stop layer 802. The ILD layer 1204 may be materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In an embodiment, the ILD layer 1204 is SiO₂. The ILD layer 1204 may be different than, or the same composition as, the ILD layer 804. The ILD layer 1204 and/or etch stop layer 1202 may be deposited by a CVD process, a flowable CVD (FCVD) process, a spin-on coating process, or other suitable deposition technique.

In an embodiment, the dielectric layers 1202, 1204 are patterned to provide for metal layer 1206. The metal layer 1206 may include metal lines extending in a first direction on the substrate, such as perpendicular to a direction of the gate structure and/or parallel the direction of the fin elements of the active region-for example, the x-direction of FIG. 12A. Metal layer 1206 may include copper, additional liner or adhesion layers, and/or other suitable conductive materials. In an embodiment, at least one metal line of the metal layer 1206 is connected to the source-side via 1104. And in an embodiment, at least one metal line of the metal layer 1206 is connected to the drain-side via 1102. In an embodiment, at least one line, e.g., a line connected to the source-side via 1104, of the metal layer 1206 forms a power rail. The source-side via 1104 and the contact 702 formed on the source feature of a transistor provide a path from a power rail of the metal layer 1206 to the source of the transistor.

Referring to FIGS. 2, method 200 proceeds to block 222 where further processing is performed. The further processing may include additional MLI features. For example, such additional processes may include formation of gate contact vias to couple to the gate structure 302. Additional processes further include additional metallization layers (e.g., metal lines) and vertically extending vias, surrounding dielectrics (e.g., ILD) to further route and combine the signals from the transistors. Some of the additional MLI features may be formed concurrently with block 220 or prior to block 220.

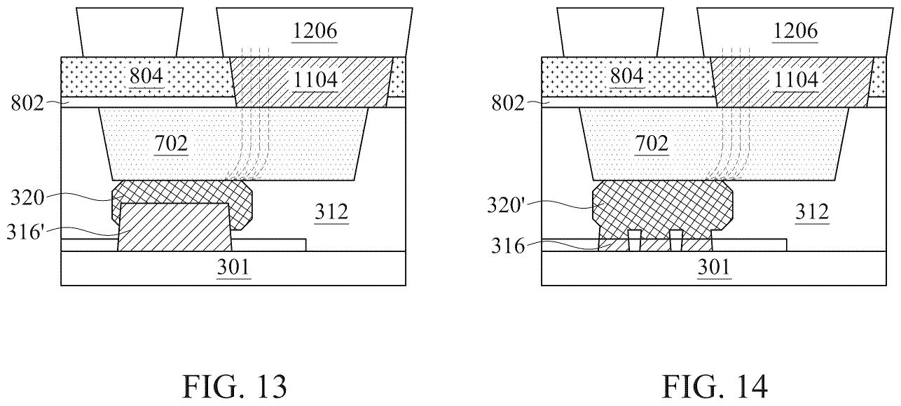

Referring to FIGS. 13, 14, 15A, 15B, 16A, 16B, and 16C, illustrated are additional embodiments of the device 100 of FIGS. 1A, 1B and device 300 described above with reference to FIGS. 2-12D. It is noted that the embodiments of FIGS. 13-16C share common features with those discussed previously, with specific differences illustrated for case of reference. The embodiments of FIGS. 13-16C are illustrative only and not intended to be limiting. FIG. 13 illustrates an embodiment where an active region, such as active region 110/310, includes a single fin illustrated as fin 316′. FIG. 14 illustrates an embodiment where the source/drain features 320′ are formed by recessing fin, and forming the source/drain features with the fin recesses. Thus, the epitaxially-grown source/drain features 320′ may include a lower portion having a fin like shape and an upper, merged portion. It is noted FIG. 1B illustrates an embodiment where the source/drain features 120 are formed by epitaxial growth on a plurality of fins 116, where the epitaxial growth “wraps” or extends along vertically extending sidewalls of the fins. FIG. 1B illustrates a merged source/drain 120 where source/drains of adjacent fins 116 merge together. In other implementations, the source/drain features may be separated by insulating material. Other source/drain configurations are also suitable.

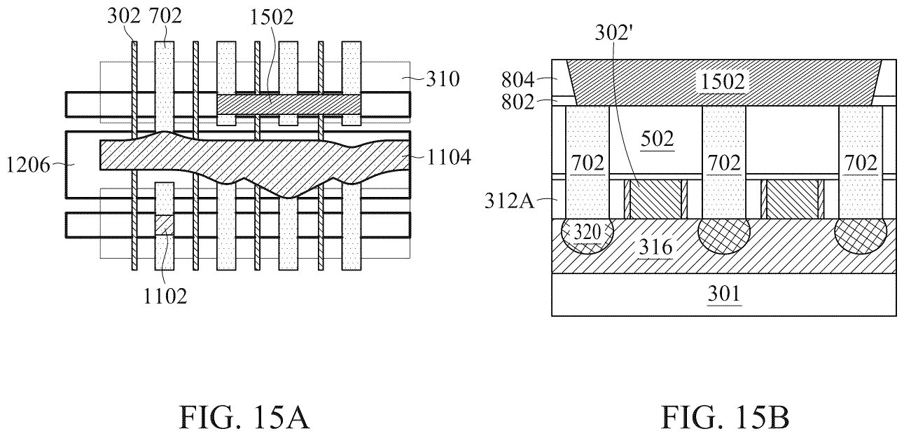

FIGS. 15A and 15B are illustrative of vias associated with a terminal of the transistor (e.g., drain-side vias) are a contiguous via extending between contact structures. In particular, the drain-side vias are contiguously extending between adjacent device-level contact structures formed on drain features (e.g., epitaxial drain feature). The drain-side vias 1502 may be substantially similar to drain-side vias 1102, except providing a contiguous structure between multiple devices of the active region. In an embodiment, the drain-side via is rectangular in structure having linear sidewall outline from a top view. It is noted that as illustrated in FIG. 15A, a device may include both drain-side vias 1502 (interfacing a plurality of contacts 702) and drain-side vias 1102 (interfacing a single contact 702).

FIGS. 16A, 16B and 16C illustrate different shapes each illustrating an embodiment of an undulating-shape via. The undulating-shape vias of FIGS. 16A, 16B, and 16C may be fabricated using the method 200. FIG. 16A illustrates concave portions and convex portions of an undulating-shape via 1602 are defined by substantially linear sidewalls extending transverse to a horizontal line drawn in the top view (i.e., transverse to a line extending in the x-direction). The linear sidewalls may be transverse to a line parallel to the active region (e.g., fin) and orthogonal to the gate lines. As illustrated, the transverse sidewalls may produce concave portions or recesses of the via that are triangular-shaped 1602B. And the transverse sidewalls may produce convex portions or protrusions of the via that are triangular-shaped 1602A.

FIG. 16B illustrates concave portions and convex portions of an undulating-shape via 1604 that are defined by substantially linear sidewalls extending orthogonal to a horizontal line drawn in the top view (i.e., extending in the x-direction), and a substantially linear sidewall, connecting the orthogonal sidewalls, which extends parallel to a horizontal line drawn in the top view. As illustrated, the sidewalls may produce concave portions or recesses of the via that are rectangular-shaped 1604B. And the orthogonal sidewalls may produce convex portions or protrusions of the via that are rectangular-shaped 1604A.

FIG. 16C illustrates concave portions and convex portions of the undulating-shape via 1606 formed by curved or curvilinear sidewalls. It is noted that in some embodiments, linear sidewalls of the via extend between the curvilinear sidewalls. In some instances, the curvilinear sidewalls abut one another providing an inflection point at the junction of a curved falling sidewall and a curved rising sidewall. As illustrated, the curvilinear sidewalls may produce concave portions or recesses of the via that are semicircle-shaped 1606B. And the curvilinear sidewalls may produce convex portions or protrusions of the via that are semicircle-shaped 1606A.

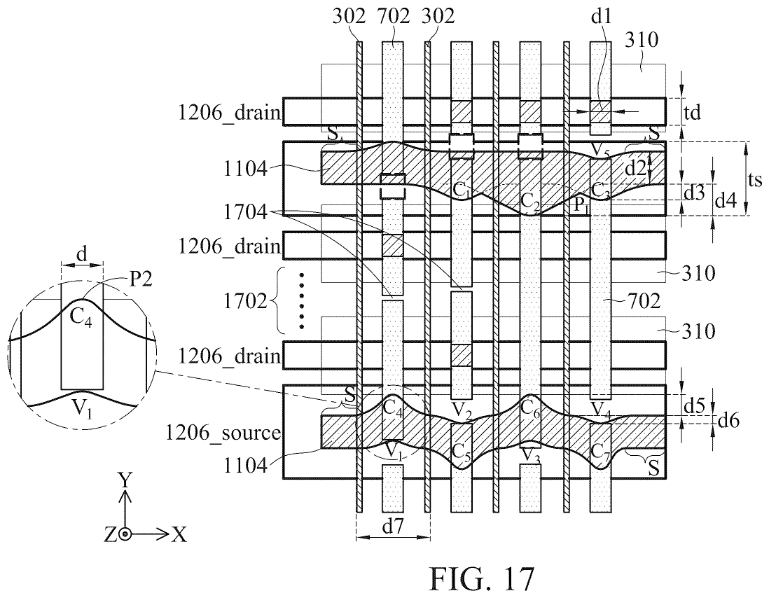

Referring now to FIG. 17, illustrated is a plan view of a layout 1700 of a device. The layout 1700 may be substantially similar to that of the device 100 of FIGS. 1a and 1b, and be substantially similar to FIGS. 3A-12A providing a top view of the device 300. For example, the via 1104 may be substantially similar to the via 106 of FIGS. 1a, 1b. In some implementations, the layout 1700 illustrates a cell such as an SRAM cell. The layout 1700 is an integrated circuit layout or mask design, such as provided by electronic design automation (EDA) tools; the layout 1700 may also be illustrative of layers of a fabricated device.

The layout 1700 includes a plurality of active regions 310, a device-level contact 702 layer overlying the active regions 310, a via level over the device-level contact 702 layer where the via level includes vias 1102 and vias 1104, and a first metal layer 1206 over the via level. The first metal layer 1206 includes various metal lines extending in the x-direction. In an embodiment, the vias 1102 are drain-side vias providing connection to the device-level contact 702 that interface a drain feature of a transistor in the active region 310. The drain-side vias 1102 connect to a metal layer 1206_drain. In an embodiment, the vias 1104 are source-side vias providing connection to the device-level contact 702 that interface source features of a transistor in the active region 310. The source-side vias 1104 connect to a metal layer 1206_source.

Area 1702 of the layout 1700 illustrates that in an embodiment approximately four (4) or five (5) metallization lines, such as metal lines formed on metallization 1206, are formed. The metallization layers may be formed on a first metal layer (e.g., M0) planar with the metal layer 1206. Each of the metallization layers of area 1702 may be associated with a drain feature of a transistor in that the metallization layers are coupled to a drain feature of a transistor. In some implementations, no metallization 1206 lines associated with a source feature of a transistor are formed in area 1702. In other words, in some implementations 6 or 7 drain associated metal lines interpose source associated metal lines on the metal layer 1206.

In some implementations, the metal lines 1206_drain and the metal lines 1206_source are connected to a different voltage. In some implementations, including as shown in FIG. 17, metal lines 1206 extend parallel to one another and parallel the active region 310, for example, in an active region 310 comprising fins, the metal lines 1206 extend parallel the length of a fin. The metal line 1206_drain has a width td and the metal line 1206_source has a width ts. In an embodiment, the width ts is greater than td, as measured in a top view.

Insulating regions interpose the active regions 310. Additionally, in some implementations, isolation features 1704 may be formed between segments of the device-level contact 702. The isolation features 1704 allow for a “cut” portion to provide a first portion of the device level contact coupled to a drain feature and a second portion of the device level contact coupled to a source feature. In some implementations, a contact 702 is formed extending in a first direction (e.g., y-direction), and the contact 702 is subsequently patterned to remove or “cut” a portion of the contact line 702 and the isolation feature 1704 is formed in the region where the contact is removed. In other words, a contact element 702 may not be simultaneously connected to a source-side via 1104 and a drain-side via 1102.

In some embodiments, a metal line 1206 extends over the isolation structures 1704. In some embodiments, a metal line 1206 extends over the ends of the device-level contact 702. In some implementations, such as illustrated by FIG. 14, a metal line 1206 is vertically disposed over the active region 310, including over (and vertically aligned above) fin 116. In some implementations, such as illustrated by FIG. 14, the source-side via is vertically disposed over the active region. Thus, in some embodiments, a source path can be substantially vertical in orientation between the metal line 1206 and the transistor terminal.

As discussed herein, the undulating-shape via 1104 may be defined in different shapes. In an embodiment, the via 1104 extends from a first side of a first gate line 302 to an opposite side of a second gate line 302. One or more gate lines 302 may interpose the first and second gate line 302. In some embodiments, within a via 1104 there is a portion S that is a linear portion, the linear portion S has opposing, parallel linear sidewalls. In an embodiment, the linear portion S is substantially parallel with the metal line 1206. The via 1104 also includes convex portions labeled C (in particular, C₁-C₇). And the via 1104 includes concave portions labeled V (in particular, V₁-V₅). As discussed above, the convex portions (C) and the concave portions (V) can take various shapes including curved, semicircular, rectangular, round, oval, triangular, etc. In some implementations, the convex portions (C) and the concave portions (V) are relative to the linear portion S. As indicated above, the concave portions (V) may also be referred to as indentations. The convex portions (C) may also be referred to as protrusions.

Convex portions (C) may extend toward the active region 310 to which the via 1104 is electrically connected. In some embodiments, convex portions (C) extend toward the active region 310 to the extent that the convex portion (C) is vertically above the active region 310 (e.g., vertically above the fin 316 of the active region 310). In some implementations, the convex portions (C) may extend to further overlie the contact 702 to which it is electrically connected thereby increasing the landing area between the contact 702 and the via 1104. For example, C1, C2, C3 extend downward in the y-direction of FIG. 17 to provide a greater interface with the underlying contacts 702. Concave portions (V) may extend away from the active region 310 to which the via 1104 is not electrically connected. In particular, the concave portions (V) may extend away from the contact 702 to which it is adjacent, but electrically insulated. For example, V5 extends such that via 1104 is further from the contact 702 that lies adjacent to it in the y-direction as that portion of the contact 702 is electrically insulated from via 1102 instead being connected to the via 1102.

When several convex portions of the via 1104 extend from the same “side” of the via structure (e.g., C1, C2, C3 are located on the bottom side of the via 1104) and are each to interface the underlying respective contacts 702, the convex portions C may have different sizes. For example, in an embodiment, C1 is less than C2, C3 is less than C2. In some embodiments, C1 and C3 are less than C2 because C1 and C3 are neighboring a contact 702 that is insulated from the via 1104 including C1 and C3. If C1 and C3 were greater in distance, a leakage increase may be experienced. C2 convex portion can be larger due to no neighboring contact 702 to which it must be insulated, and thus can benefit from increased distance of the interface between the via 1104 and C2 and the underlying contact 702. In some embodiments, when concave portions and convex portions are alternatingly arranged such as illustrated by V1, V2, V3, V4, C4, C5, C6, C7, the convex portions C and/or the concave portions V are smaller (as measured in as a distance from a line collinear with the linear sidewalls S) than those in an embodiment where several concave portions or convex portions are consecutively arranged, for example as illustrated by C1, C2, C3, because the sizes of the alternatingly arranged convex and concave portions are confined by neighboring convex and concave portions.

In some embodiments, the size of the concave (V) portions of the via 1104 are limited such that the underlying contact 702, to which the via 1104 is connected, is not exposed. In some implementations, Rc increases if a portion of the contact 702 is vertically aligned outside of the via 1104. For example, V2, V4, V5 each illustrate that the convex portion is provided to a distance that the underlying contact 702 is below the via 1104 (i.e., the sidewall of the via 1104 convex portion V is substantially aligned above the end sidewall of the contact 702).

In some embodiments, the via 1104 has a shape outline defined in a top view that is provides a curved sidewall that has inflection points (see, e.g., P1). The inflection point P1 may be determined where a sidewall is extending in a first direction and transitioning to a second direction. In some embodiments, the convex part C has an apex point P2. The apex point P2 may be centered on the width of the contact 702, as measured from a top view. In other words, for the contact 702 having a width d in the top view, the apex point P2 may be positioned at d/2.

In an embodiment, the width of the metal line 1206_source (e.g., coupled to the source terminal of a transistor) has a width of ts as measured in the top view. ts may be between approximately 5 and approximately 200 nanometers (nm). In an embodiment, the width of the metal line 1206_drain (e.g., coupled to the drain terminal of a transistor) has a width of td as measured in the top view. td may be between approximately 5 and approximately 100 nanometers (nm). In an embodiment, td is less than ts, for example, at least 50% less than ts. In an embodiment, the source-side via 1104, which is an undulating-shaped via, has a width of d2 as measured in the top view. The width d2 may be between approximately 5 nm and approximately 100 nm. In an embodiment, the width d2 is less than the thickness ts. In an embodiment, the drain-side via 1102 is a rectangular-shaped via. In a further embodiment, the drain-side via 1102 is a rectangular-shaped via with substantially equal length sides. In an embodiment, the drain-side via 1102 has a width of d1 as measured from the top view. In some implementations, d1 is between approximately 5 nm and 80 nm. In an embodiment, the width d1 is substantially equal to the width td.

In an embodiment, the convex portions (C) have a distance from which they extend from an imaginary line collinear with the linear sidewall of portions S of the via 1104. This distance is exemplified as d3 for convex portion C3, d4 for convex portion C2, and d5 for convex portion C6. In an embodiment, d3 is greater than zero, d4 is greater than zero, and/or d5 is greater than zero. In a further embodiment, d3 is between approximately 0.1 nm and approximately 50 nm. In a further embodiment, d4 is between approximately 0.1 nm and approximately 100 nm. In a further embodiment, d5 is between approximately 0.1 nm and approximately 50 nm. In an embodiment, the ratio of d3 to d2 is between approximately 0.1 to 1 and 10 to 1.

In an embodiment, the concave portions (V) have a distance from which they extend from an imaginary line collinear with the linear sidewall of portions S of the via 1104. This distance is exemplified as d6 for concave portion V4. In an embodiment, d6 is greater than zero. In a further embodiment, d6 is between approximately 0.1 and 50 nm. In an embodiment, the ratio of d6 to d2 is between approximately 0.1 to 1 and 10 to 1.

As discussed above, the convex portions (C) and the concave portions (V) may be defined by a distance in the y-direction of the top view. In an embodiment, the concave portion (V) and/or convex portion C may extend a distance in the x-direction of greater than zero. In an exemplary embodiment, the convex portion C4 extends a distance of d7 in the y-direction. In an exemplary embodiment, the concave portion V1 extends a distance of d7 in the y-direction. In some implementations, d7 is between approximately 10 nm and approximately 300 nm. In an embodiment, the distance the convex portion C and/or the concave portion V extend in the x-direction may be greater than or equal to the distance between a gate 302 and an adjacent gate 302. In an embodiment, the convex portion C2 has a contour such that between an imaginary point collinear with the sidewall of S1 to an opposing imaginary point collinear with the sidewall of S1 is greater than 10 nm. In an embodiment, the convex portion C1 has a contour such that between an imaginary point collinear with the sidewall of S1 to an opposing imaginary point collinear with the sidewall of S1 is between approximately 10 and approximately 300 nm. It is noted that these dimensions defining the curve of the sidewall may be selected in a design-phase and the device as fabricated provides a sidewall with an inflection point such as P1.

The disclosure of the present disclosure provides embodiments of semiconductor devices and methods of forming the same. The devices and methods provide for forming an interconnect, such as a via extending between a contact to a source/drain feature and an overlying metal line, having a non-linear shape outline. The undulating-shaped via may include convex and/or concave portions that provide protrusions from and indentations to, respectively, a linear shaped outline. The convex and/or concave portions may vary in shape and be defined by sidewalls of varying shape and degree of linearity. The undulating-shaped via may allow for reduction in resistance of a device by increasing interfaces with the under and overlying conductive features and/or provide further separation between the undulating-shaped via and neighboring conductive features to which it is desired to be insulated. It is noted that to the extent the above disclosure uses embodiments of providing a non-linear or an undulating-shaped via to provide a source-side connection to a transistor, this is exemplary only and the via may be applied in the interconnect to other transistor features in other embodiments within the scope of the disclosure.

In one embodiment, a method of manufacturing a semiconductor structure is provided. The method includes providing a substrate having a first source/drain feature formed over the substrate. A first contact structure is formed on the first source/drain feature. A dielectric layer is deposited over the first contact structure. The method continues to include etching an opening in the dielectric layer to define a via opening. And the opening in the dielectric layer has a non-linear shape in a plan view. The opening is filled with conductive material to form a via connected to the first contact structure. A metal line is formed above the via.

In an implementation of the method, providing the substrate includes epitaxially growing the first source/drain feature on a fin extending from the substrate. The method may further include forming the first contact by depositing a metal layer on the epitaxially grown first source/drain feature and forming a silicide between the epitaxially grown first source/drain feature and the metal layer. In an embodiment, depositing the dielectric layer includes depositing an etch stop layer and an interlayer dielectric (ILD) layer. In an embodiment, filling the opening with conductive material includes depositing a metal directly on the first contact structure by a bottom-up deposition process. In some implementations, filling the opening includes completely filling the opening with the metal. In an embodiment, etching the opening having the non-linear shape includes forming a shape having a protrusion over the first contact structure in a plan view. In a further embodiment, etching the opening having the non-linear shape includes forming the opening having the protrusion at a first region of the opening and an indentation at a second region of the opening. The first region may be a distance from the second region in the plan view.

In another embodiment, a method is provided. The method of manufacturing a semiconductor structure includes forming a first gate structure and a second gate structure each extending in a first direction. The method continues to providing a first source/drain feature between the first gate structure and a first side of the second gate structure and a second source/drain feature adjacent a second side of the second gate structure. A first contact structure extending in a second direction is provided. The first contact structure interfaces the first source/drain feature. A second contact structure is provided extending in the second direction. The second contact structure interfaces the second source/drain feature. The second direction is perpendicular the first direction. A via structure is formed extending in the first direction from an interface with the first contact structure to an interface with the second contact structure. The via structure is an undulating-shape in a top view.

In a further embodiment, forming the via structure includes depositing a dielectric layer over the first contact structure and the second contact structure, defining a masking element on the dielectric layer where the masking clement defines the undulating-shape; etching an opening having the undulating-shape in the dielectric layer; and filling the undulating-shape opening with a metal. In an embodiment, filling the undulating-shape opening with the metal includes a bottom-up deposition process of the metal directly on the first contact structure and the second contact structure.

In an embodiment, the forming the via structure includes forming the via structure having a first convex portion over the first contact structure and a second convex portion over the second contact structure. In a further implementation, the first convex portion has a first distance to its apex in the first direction and the second convex portion has a second distance to its apex in the first direction. The second distance may be greater than the first distance. In an embodiment, forming the via structure includes forming the via structure having a concave portion between the first convex portion and the second convex portion. In an embodiment, the method includes forming a third contact structure extending in the first direction. The concave portion is aligned with the third contact structure in the first direction.

In a further embodiment, a semiconductor device is provided. The semiconductor device includes a first gate structure and a second gate structure extending in a first direction. A first source/drain feature is between the first gate structure and a first side of the second gate structure and a second source/drain feature is adjacent a second side of the second gate structure. A first contact structure extends in a second direction and interfaces the first source/drain feature. A second contact structure extends in the second direction and interfaces the second source/drain feature. The second direction is perpendicular the first direction. A via structure extends in the first direction. The via structure interfaces the first contact structure and the second contact structure. The via structure is a non-linear shape in a top view.

In an embodiment, the non-linear shape includes a plurality of convex region and a plurality of concave regions. In a further embodiment, a first convex region of the plurality of convex regions interfaces the first contact structure and a second convex region of the plurality of convex regions interfaces the second contact structure. In a further implementation, at least one convex region of the plurality of convex regions interposes the first and second convex regions. In an embodiment, the first convex region is defined by curved sidewalls when viewed from the top view.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a first gate structure and a second gate structure extending in a first direction;
a first source/drain feature between the first gate structure and a first side of the second gate structure and a second source/drain feature adjacent a second side of the second gate structure;
a first contact structure extending in the first direction, the first contact structure interfacing the first source/drain feature and a second contact structure extending in the first direction, the second contact structure interfacing the second source/drain feature; and
a via structure extending in a second direction, wherein the via structure interfaces the first contact structure and the second contact structure, wherein the via structure is a non-linear shape in a top view and the second direction different than the first direction.

2. The semiconductor device of claim 1, wherein the non-linear shape includes a plurality of convex regions and a plurality of concave regions.

3. The semiconductor device of claim 2, wherein a first convex region of the plurality of convex regions interfaces the first contact structure and a second convex region of the plurality of convex regions interfaces the second contact structure.

4. The semiconductor device of claim 3, wherein at least one convex region of the plurality of convex regions interposes the first and second convex regions.

5. The semiconductor device of claim 3, wherein the first convex region is defined by curved sidewalls when viewed from the top view.

6. The semiconductor device of claim 1, wherein the via structure is disposed over an end of the first contact structure.

7. The semiconductor device of claim 6, wherein the via structure is disposed over an insulating material abutting the end of the first contact structure.

8. The semiconductor device of claim 7, wherein a bottommost surface of the via structure interfaces each of the insulating material that the first contact structure.

9. A semiconductor device, comprising:
a gate structure;
a first source/drain region adjacent the gate structure;
a contact structure on the first source/drain region;
a via structure over the contact structure, wherein at least a portion of the via structure interfaces the contact structure, wherein the via structure in a plan view has a non-linear shape; and
a metal line extending above the via structure.

10. The semiconductor device of claim 9, wherein in the plan view the gate structure extends in a first direction and the via structure extends in a second direction perpendicular to the first direction.

11. The semiconductor device of claim 9, further comprising:
an insulating material extending from interfacing the first source/drain region to interfacing a bottom surface of the via structure.

12. The semiconductor device of claim 9, wherein the metal line extends an entirety of a width of the via structure.

13. The semiconductor device of claim 9, further comprising:
another via structure coplanar with the via structure, wherein the another via structure is of rectangular shape in the plan view.

14. The semiconductor device of claim 9, wherein the via structure has tapered sidewalls in a cross-sectional view.

15. A semiconductor structure, comprising:
a first gate structure, a second gate structure, and a third gate structure each extending in a first direction in a plan view;
a first source/drain feature between the first gate structure and a first side of the second gate structure and a second source/drain feature adjacent a second side of the second gate structure and a first side of the third gate structure;
a first contact structure extending in the first direction, the first contact structure interfacing the first source/drain feature and a second contact structure extending in the first direction, the second contact structure interfacing the second source/drain feature; and
forming a via structure extending in a second direction in the plan view, the via structure having an interface with the first contact structure to an interface with the second contact structure, wherein the via structure is an undulating-shape in the plan view.

16. The semiconductor structure of claim 15, further comprising:
a metal line extending in the second direction, wherein the metal line is disposed over the via structure.

17. The semiconductor structure of claim 16, wherein the metal line has a first width in the first direction in the plan view and the via structure has a second width in the plan view in the first direction, and wherein the first width is greater than the second width.

18. The semiconductor structure of claim 15, further comprising:
a dielectric layer over the first contact structure and the second contact structure, wherein the via structure is formed within the dielectric layer.

19. The semiconductor structure of claim 15, further comprising:
a third contact structure coplanar with the first and second contact structures, wherein the via structure has a concave sidewall aligned with and spaced a distance from the third contact structure in the plan view.

20. The semiconductor structure of claim 19, further comprising
an active region extending in the second direction.
